(19) United States
(12) Patent Application Publication
(10) Pub. No.: US 2012/0133613 A1
(43) Pub. Date: May 31, 2012

(54) CAPACITIVE TOUCH PANEL

(75) Inventors: Xiaochuan CHEN, Beijing (CN); Wei LI, Beijing (CN); Xiaokun LI, Beijing (CN)

(73) Assignee: Beijing BOE Optoelectronics Technology Co., Ltd., Beijing (CN)

(21) Appl. No.: 13/305,953

(22) Filed: Nov. 29, 2011

(30) Foreign Application Priority Data
Nov. 29, 2010 (CN) 201010571669.8

(51) Int. Cl. G06F 3/045; H03K 17/975

(52) U.S. Cl. 345/174; 200/5 A

(57) ABSTRACT

Embodiments of the present disclosure provide a capacitive touch panel capable of simplifying a manufacture process thereof. The capacitive touch panel comprises a first substrate and a second substrate provided opposite to each other, wherein a common electrode and at least two parallel electrode lines are disposed between the first substrate and the second substrate, at least two touch electrodes are connected in series by each of the electrode lines, any two of the touch electrodes connected by a same electrode line have an area different from each other, varying sequentially, the touch electrode and the common electrode form a capacitor, and the electrode line is connected to a touch signal sensing device. The capacitive touch panel provided by embodiments of the present disclosure may achieve one-dimensioned positioning.

### BACKGROUND

Embodiments of the disclosed technology relate to a capacitive touch panel.

Capacitive touch panels are a relatively popular type of existing touch panels. A capacitive touch panel works as follows.

Row electrodes and column electrodes are disposed in the capacitive touch panel, as shown in FIG. 1 and FIG. 2. The row electrodes and the column electrodes are insulated from each other, and they each faint a capacitor together with a common electrode. As a human body is conductive, touching a surface of the capacitive touch panel with a finger results in a coupling capacitance formed between the finger and row and column electrodes of the touch panel. Due to the change of capacitance at the touching point, currents are respectively induced in the row and column electrodes, flowing towards the touching point. The induced current each has intensity inversely proportional to a distance between the finger and a boundary of the touch panel. Positions of the touching point can be accurately determined by measuring of the induced currents with sensors disposed at both ends of the row and column electrodes.

In practicing the above capacitive touch panel, the inventors has found that there are at least following problems.

Most of the existing capacitive touch panels employ a structure of such row and column electrodes and determine the positions of a touching point by sensing changes in currents or change of pulse signals over the row and column electrodes. However, such structure of the capacitive touch panel needs to fabricate a plurality of layers, such as a row electrode layer, a column electrode layer, a common electrode layer, and insulating or protective layers between various conductive layers. Thus, the fabrication process is complicated, and especially, wiring is relatively difficult in a small-sized touch panel.

### SUMMARY

An embodiment of the present disclosure provides a capacitive touch panel capable of simplifying a manufacture process for forming the touch panel.

An embodiment of the disclosed technology provides a capacitive touch panel comprising a first substrate; and a second substrate provided opposite to the first substrate, wherein a common electrode and at least two parallel electrode lines are disposed between the first substrate and the second substrate, at least two touch electrodes are connected in series along each of the electrode lines, and any two of the touch electrodes connected by same one electrode line have areas different from each other; and each of the touch electrodes and the common electrode form a capacitor, and each of the electrode lines is connected to a touch signal sensing device.

Another embodiment of the disclose technology provides a display device comprising: the above-described capacitive touch panel; and a display panel, wherein the capacitive touch panel are provided on the display panel.

In the capacitive touch panel according to an embodiment of the present disclosure, a plurality of touch electrodes having an area different from one another may be disposed on same one electrode line. In this case, since touch points correspond to the touch electrodes having different areas, the change in capacitance at the touched touch point due to a coupling capacitance occurred between the finger and the touched touch electrode during a touching operation is different from that at other touch points. Further, the intensity of an electric signals detected by the touch signal sensing device connected to the respective touch electrode line are also different from each other. Thus, a specific touch point can be determined on the touch electrode line 4 according to the intensity of the detected electric signals. In addition, since location of each of the touch electrode lines is fixed, information about location of the touch electrode lines may be stored in advance in a controlling module of the capacitive touch panel so as to determine the location of the touch point accurately and quickly. With the capacitive touch panel provided by the above embodiments, positioning of the touch point may be achieved so long as one layer of the electrode lines is provided and the electrode lines extend in a same direction. Accordingly, in the manufacture process for the capacitive touch panel, the electrode lines in the other direction can be eliminated, thereby simplifying the manufacture process for the capacitive touch panel.

Further scope of applicability of the present disclosure will become apparent from the detailed description given hereinafter. However, it should be understood that the detailed description and specific examples, while indicating preferred embodiments of the disclosure, are given by way of illustration only, since various changes and modifications within the spirit and scope of the disclosure will become apparent to those skilled in the art from the following detailed description.

### BRIEF DESCRIPTION OF THE DRAWINGS

The drawings, which are necessary for following description of embodiments of the present disclosure, will now be described briefly in order to more fully disclose embodiments of the present disclosure or approaches of the prior art. It is to be easily understood by those skilled in the art that the drawings show merely some embodiments of the present disclosure and some other drawings may be obtained on the basis of the following drawings without any mental work.

FIG. 1 is a schematic plan view showing structure of an existing capacitive touch panel.

FIG. 2 is a schematic plan view showing structure of another existing capacitive touch panel.

FIG. 3 is a schematic plan view showing structure of a capacitive touch panel according to an embodiment of the present disclosure.

FIG. 4 is a cross sectional view of a capacitive touch panel taken along a line A-A in FIG. 3.

FIG. 5 is a schematic view showing structure of a capacitive touch panel while it is not touched, according to an embodiment of the present disclosure.

FIG. 6 is a schematic view showing structure of a capacitive touch panel while it is being touched, according to an embodiment of the present disclosure.

FIG. 7 is a schematic plan view showing structure of a capacitive touch panel according to another embodiment of the present disclosure.

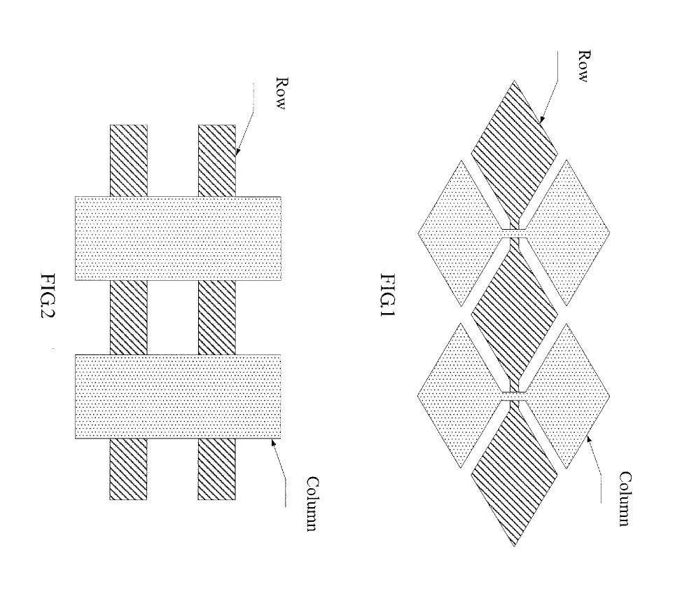

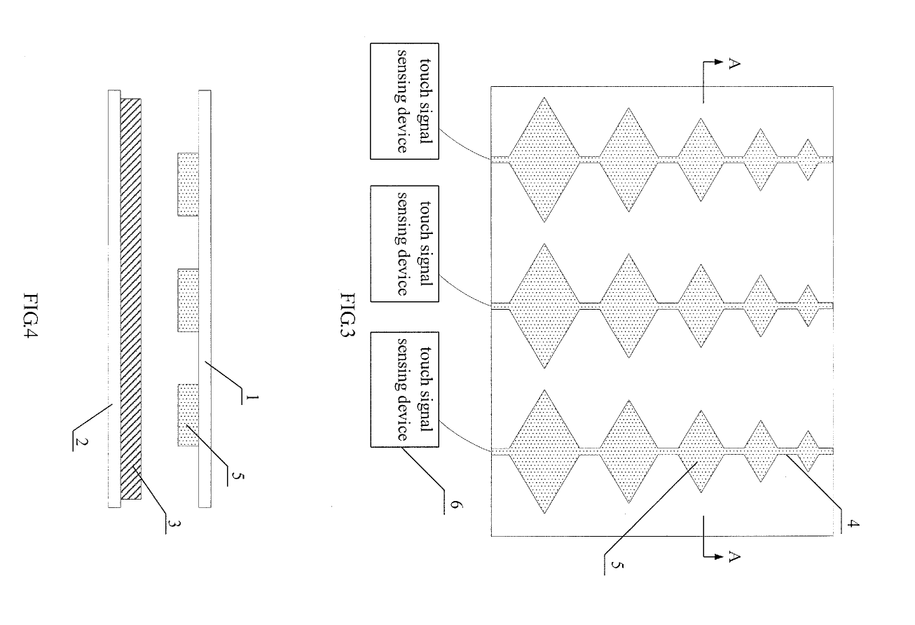

### DETAILED DESCRIPTION

Embodiments of the present disclosure will now be described more fully and clearly hereinafter with reference to the accompanying drawings in which the embodiments of the present disclosure are shown. It is to be recognized by those skilled in the art that the embodiments set forth herein is merely a part rather than all of the present disclosure. All other embodiments that can be obtained by those skilled in the art on the basis of the disclosed embodiments without any mental work fall within the scope of the present disclosure.

In order to simplify a process for manufacturing a capacitive touch panel, an embodiment of the present disclosure provides a capacitive touch panel as below.

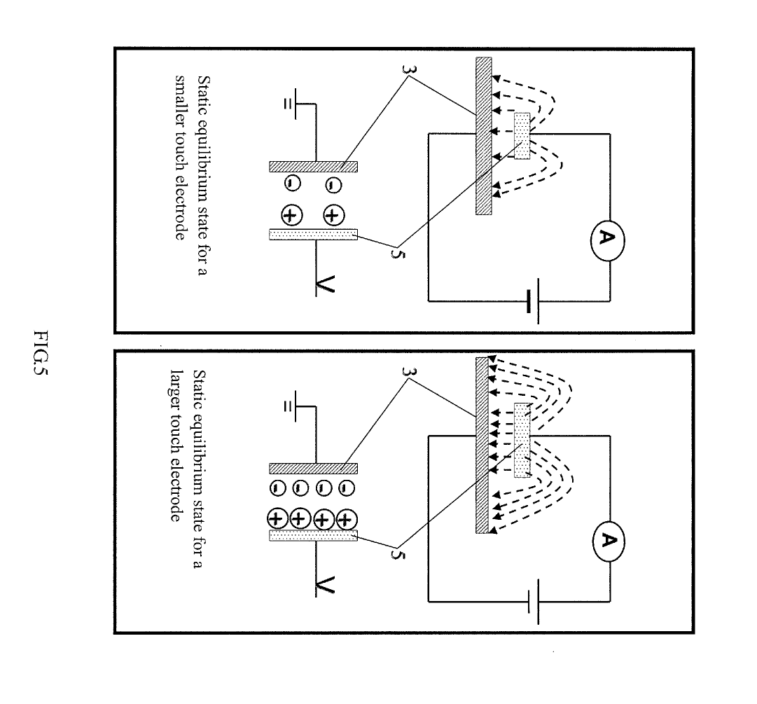

FIG. 3 is a schematic plan view showing structure of a capacitive touch panel according to an embodiment of the present disclosure; FIG. 4 is a cross sectional view of the capacitive touch panel taken along a line A-A in FIG. 3. With reference to FIG. 3 and FIG. 4 in combination, the embodiment of the present disclosure provides a capacitive touch panel comprising a first substrate 1 and a second substrate 2 disposed opposite to each other. A common electrode 3 and at least two parallel electrode lines 4 are provided between the first substrate 1 and the second substrate 2; the common electrode 3 and the at least two parallel electrode lines 4 are provided on the second and the first substrates, respectively. At least two touch electrodes 5 are connected in series by each of the electrode lines 4, and any two touch electrodes 5 connected by a same electrode line 4 have an area different from each other. The touch electrode 5 each forms a capacitor along with the common electrode 3. The electrode line 4 is connected with a touch signal sensing device 6.

For example, the touch signal sensing device 6 may be disposed at an end of each electrode line 4 and positioned at a same side of the capacitive touch panel as the electrode lines 4.

FIG. 3 shows a layout of the electrode lines 4 that extend parallel in a longitudinal direction. However, the layout of the electrode lines 4 is not limited thereto. In addition to the longitudinal arrangement, the electrode lines 4 may also be arranged in a transverse or inclined direction. It is preferred in current embodiment that the electrode lines 4 extend parallel to each other in the longitudinal or transverse direction since the touch electrodes 5 connected in series by the respective electrode lines 4 may be arranged more regularly.

In the forgoing capacitive touch panel, a plurality of touch electrodes 5 having an area different from one another are disposed on same one electrode line 4. In this case, since different touch points correspond to the touch electrodes 5 having different surface areas, the change in capacitance at one touch point due to the coupling capacitance occurred between the finger and the touch electrode, which is touched during a touching operation, is different from that at the other touch points. Further, the intensity of the electric signals detected by the touch signal sensing devices 6 connected to the respective touch electrode lines 4 are also different from each other. Thus, a specific touch point can be determined on the touch electrode line 4 according to the intensity of the detected electric signal. In addition, in an example, since location of each of the touch electrode lines 4 is fixed, information about location of the touch electrode lines 4 may be stored in advance in a controlling module of the capacitive touch panel, so that the location of the touch point can be determined accurately and quickly.

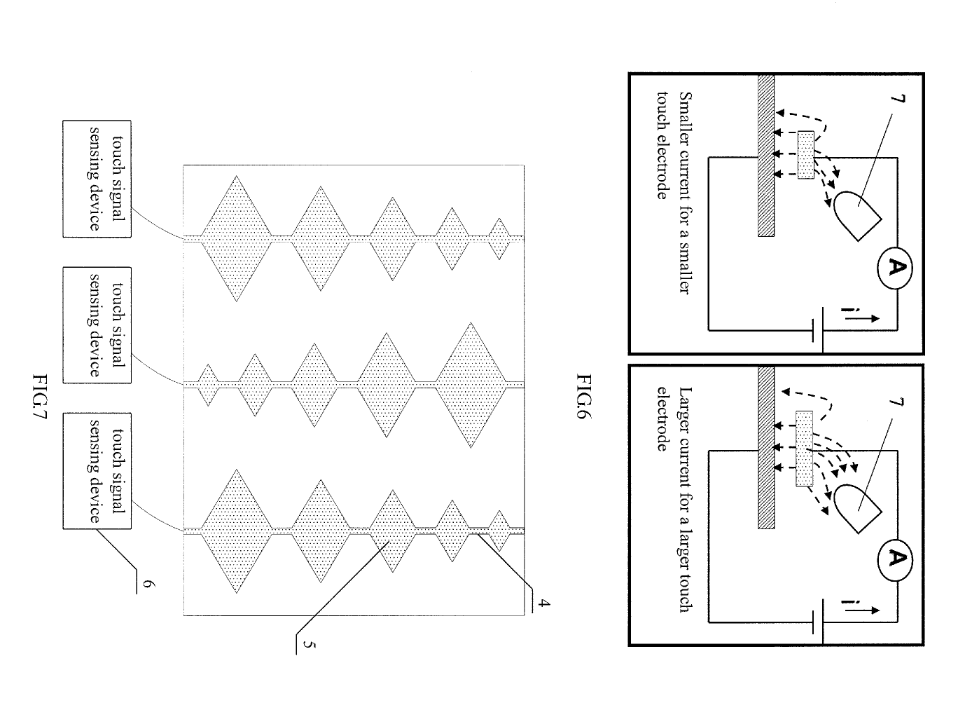

In particular, as shown in FIG. 5, when the capacitive touch panel is not touched, the touch electrode 5 and the common electrode 3 form a capacitor that is in a static equilibrium state. When a finger 7 is touching the surface of the capacitive touch panel, as shown in FIG. 6, a coupling capacitance occurs between the finger 7 and one touch electrode 5 such that the capacitance between the touch electrode 5 and the common electrode 3 varies. Further, it may be understood that since the contact area between the finger and the capacitive touch panel is larger than an average area of the touch electrodes 5, the change amount in capacitance is in association only with the area of the touched touch electrode 5. During the touching operation, a touch electrode 5 having a relatively larger area has a larger change in capacitance and thus generates a larger induced current; on the other hand, a touch electrode 5 having a relatively smaller area has a smaller change in capacitance and thus generates a smaller induced current.

The touch signal sensing devices 6, which are connected to the touch electrode lines 4, respectively, can detect intensity of the induced currents and output the detected current values to the control module of the capacitive touch panel. The control module can determine location of the touch point on the touch electrode line 4 according to a correspondence relationship between the current value and the coordinate (e.g., the relationship between the current I and the coordinate Y shown in Table 1 below) that is stored therein in advance. Meanwhile, with reference to location information of the touch electrode lines 4 stored therein, the control module can determine the exact location of the touch point on one of the touch electrode lines 4.

TABLE 1

| Current | I₁ | I₂ | . . . | Iₙ |
|---|---|---|---|---|
| Coordinate | Y₁ | Y₂ | . . . | Yₙ |

The data in the table 1 is obtained for the case where the touch electrode lines 4 extend parallel in the longitudinal direction. At this time, a longitudinal coordinate of the touch point on the touch electrode line 4 may be obtained according to the current detected by the touch signal sensing device 6 connected to this touch electrode line 4. Meanwhile, the exact location of the touch point on the capacitive touch panel may be obtained with reference to the transverse coordinate of the touch electrode line 4 stored in the control module of the capacitive touch panel.

The data in the above table 1 can be obtained through tests before the capacitive touch panel is put into use, and the data is stored for determination of the touch point in operation of the capacitive touch panel.

It is to be understood that the embodiments of the present disclosure are not limited to use the induced current to determine location of the touch point. The touch signal sensing device 6 may serves to detect other forms of electric signals, such as voltage, pulse signal, or the like. However, the following embodiments will still take current as an example to describe the capacitive touch panel according to the embodiment of the present disclosure.

Still referring to the capacitive touch panel shown in FIG. 3, the at least two touch electrodes 5 that are connected in series by same one touch electrode line 4 may have areas sequentially increased or decreased. With reference to the structure of the capacitive touch panel shown in FIG. 3, in particular the touch electrodes 5 connected in series by same one touch electrode line 4 have areas sequentially increased or decreased from the top to the bottom in the longitudinal direction.

Provided that the at least two touch electrodes 5 connected in series by same one touch electrode line 4 have different areas, the touch signal sensing device 6 can detect electric signals with different intensity, and therefore the location of the touch point can be determined according to the different intensity of the detected electric signals. In the present disclosure, it is preferable to set a rule for varying of area of the touch electrodes 5 connected in series by the same touch electrode line 4 such that the current induced while touching the touch electrodes 5 shows a corresponding regularity. With such a configuration, it is possible to simplify the manufacture process for the capacitive touch panel and improve accuracy of positioning of the touch point.

In addition, as to the touch electrodes 5 disposed on two neighboring electrode lines 4, area change thereof may have a same tendency in a same direction, as shown in FIG. 3, or a reverse tendency in the same direction, as shown in FIG. 7.

In the structure shown in FIG. 3, when the effect of the resistance of the touch electrode line 4 on intensity of the induced current is taken into consideration, it may be preferable that the touch signal sensing device 6 is disposed at an end of the touch electrode line 4 closer to the touch electrode 5 that has a relatively large area. As such, in a touching operation, the touch electrode 5 with a relative large area generates a relative high induced current while the resistance between the touch electrode 5 and the touch signal sensing device 6 is low, and the touch electrode 5 with a relative small area generates a relative low induced current while the resistance between the touch electrode 5 and the touch signal sensing device 6 is large. In this case, difference between currents in relation to various touch electrodes 5 detected by the touch signal sensing device 6 may be further increased, and therefore accuracy of positioning (position determination) of the touch point can be further improved.

If the resolution of the capacitive touch panel decreases as the surface areas of the touch electrodes 5 increase sequentially, the configuration as shown in FIG. 7 can be employed. Since the touch electrodes 5 have a varying tendency reverse between two neighbouring electrode lines 4, the interval between the two neighboring electrode lines 4 can be decreased as compared with that shown in FIG. 3 and only need to be greater than (maximal width of the touch electrode+minimal width of the touch electrode)/2. In addition, when an induced current corresponding to a touch electrode on an electrode line is too small to determine the position of the touch point, a current detected on an adjacent electrode line may be used as assistant or reference.

In the above-described capacitive touch panel, each touch electrode line and the at least two touch electrode connected in series by the electrode line are preferably formed as an integral structure so that they can be fabricated at a same level in the manufacture process, thereby simplifying the manufacture process.

In the above-described capacitive touch panel, the common electrode, the electrode line and the touch electrode may all be made of a transparent material, for example, nano indium tin oxide (nano-ITO). Space between the first substrate and the second substrate may form a cavity or be further filled with a transparent insulation material such that the common electrode and the touch electrode can form a capacitor while transmittance of light therethrough is not substantially affected.

In the case of cavity, the common electrode and the touch electrode may be disposed on the first substrate and the second substrate, respectively; in the case of filling a transparent insulation material, the common electrode, the transparent insulation material and the touch electrode may be formed sequentially on the first substrate or the second substrate.

In the forgoing embodiments, the shape of the touch electrodes is not limited. In addition to the rhombus as shown in FIG. 3, the touch electrode may also have a rectangular shape, a circular shape, an elliptical shape, a triangle shape or any other planar shape.

In the forgoing embodiments and drawings showing embodiments of the present disclosure, the capacitive touch panel according to embodiments of the disclosure is described in terms of longitudinal extension of the electrode line. However, as discussed above, the capacitive touch panel according to embodiments of the disclosure may have the electrode lines extending parallel in the transverse direction. Such structure is substantially the same as that of the longitudinal arrangement except that the direction is different, and thus a description thereof is omitted.

With the capacitive touch panel provided by the above embodiments, positioning of the touch point can be achieved so long as one layer of the electrode lines is provided and the electrode lines extend in a same direction. Accordingly, in the manufacture process for the capacitive touch panel, the electrode lines in the other direction can be eliminated, thereby simplifying the manufacture process for the capacitive touch panel. In addition, the present disclosure may achieve one-dimensioned positioning, and the touch signal sensing device may not be used in another dimension, thereby reducing number of the used touch signal sensing devices and thus the cost.

Another embodiment of the disclosure provides a display device, which comprises any of the above-described capacitive touch panel and a display panel, and the capacitive touch panel are provided on the display panel by, for example, attaching to the display panel or integratedly formed with the display panel. The examples of the display panel include liquid crystal display (LCD) panel, organic light-emitting display (OLED) panel, light-emitting display panel, plasma display panel, and the like. In the case where the capacitive touch panel is integratedly formed with the display panel, the upper surface of the display panel is used as a substrate of the capacitive touch panel.

While the present disclosure has been shown and described with regard to certain preferred embodiments, it is to be understood that modifications in form and detail will no doubt be developed by those skilled in the art upon reviewing this disclosure. It is therefore intended that the following claims cover all such alterations and modifications that nevertheless include the true spirit and scope of the inventive features of the present disclosure.

What is claimed is:

1. A capacitive touch panel comprising:
a first substrate; and
a second substrate provided opposite to the first substrate,
wherein a common electrode and at least two parallel electrode lines are disposed between the first substrate and the second substrate, at least two touch electrodes are connected in series along each of the electrode lines, and any two of the touch electrodes connected by same one electrode line have areas different from each other; and
each of the touch electrodes and the common electrode form a capacitor, and each of the electrode lines is connected to a touch signal sensing device.

2. The capacitive touch panel as in claim 1, wherein the touch signal sensing device is disposed at an end of each of the electrode lines.

3. The capacitive touch panel as in claim 1, wherein the parallel electrode lines extend parallel in a longitudinal or a transverse direction.

4. The capacitive touch panel as in claim 1, wherein the at least two touch electrodes connected in series by the same electrode line have areas sequentially increased or decreased.

5. The capacitive touch panel as in claim 4, wherein along a same direction, the touch electrodes have areas varying in a same tendency between two adjacent electrode lines.

6. The capacitive touch panel as in claim 5, wherein the touch signal sensing device is connected to an end of the electrode line closer to the touch electrode that has a relative larger area.

7. The capacitive touch panel as in claim 4, wherein along a same direction, the touch electrodes have areas varying in a reverse tendency between two adjacent electrode lines.

8. The capacitive touch panel as in claim 1, wherein each electrode line and the at least two touch electrode connected in series by the electrode line are of an integral structure.

9. The capacitive touch panel as in claim 1, wherein the common electrode and the touch electrodes are provided on the first substrate and the second substrate, respectively, and a cavity is formed between the first substrate and the second substrate.

10. The capacitive touch panel as in claim 1, wherein the common electrode and the touch electrodes both are provided on the first substrate or the second substrate, and an insulating layer is formed between the first substrate and the second substrate.

11. The capacitive touch panel as in claim 1, wherein the common electrode, the electrode line and the touch electrode are formed of a transparent conductive material.

12. The capacitive touch panel as in claim 11, wherein the transparent conductive material comprises nano indium tin oxide.

13. The capacitive touch panel as in claim 1, wherein the touch electrode has a shape of rhombus, rectangular, circular, elliptical, or triangle.

14. A display device comprising:
the capacitive touch panel according to claim 1; and
a display panel,
wherein the capacitive touch panel are provided on the display panel.

15. The display panel according to claim 14, wherein the display panel comprises liquid crystal display (LCD) panel, organic light-emitting display (OLED) panel, light-emitting display panel, or plasma display panel.

16. The display panel according to claim 14, wherein the capacitive touch panel is attached to the display panel or integratedly formed with the display panel.
